(19) United States
(12) Patent Application Publication
(10) Pub. No.: US 2026/0282754 A1
(43) Pub. Date: Sep. 17, 2026

(54) MAGNETORESISTIVE DEVICE AND MAGNETIC MEMORY

(71) Applicant: TDK Corporation, Tokyo (JP)

(72) Inventors: Shuji OKAME, Tokyo (JP); Tomoyuki SASAKI, Tokyo (JP); Atsushi TSUMITA, Tokyo (JP)

(73) Assignee: TDK Corporation, Tokyo (JP)

(21) Appl. No.: 19/167,263

(22) PCT Filed: Mar. 23, 2023
(86) PCT No.: PCT/JP2023/011420

§ 371 Date: Sep. 19, 2025

(51) Int. Cl. H10N 50/10; G11C 11/16; H10B 61/00; H10N 50/85

(52) U.S. Cl. CPC H10N 50/10; G11C 11/161; G11C 11/1673; G11C 11/1675; H10B 61/22; H10N 50/85

(57) ABSTRACT

A magnetoresistive device includes: a substrate; a first magnetoresistive effect element; a first layer sandwiched between the substrate and the first magnetoresistive effect element; and a second layer located at a position farther from the substrate than the first magnetoresistive effect element in a stacking direction. The first magnetoresistive effect element includes a stack, a spin-orbit torque wiring in contact with the stack, a first via wiring connected to the spin-orbit torque wiring, and a second via wiring connected to the spin-orbit torque wiring at a position different from the first via wiring. The stack includes a first ferromagnetic layer, a second ferromagnetic layer, and a non-magnetic layer sandwiched between the first ferromagnetic layer and the second ferromagnetic layer. The first layer or the second layer includes an insulating first magnetic layer.

### TECHNICAL FIELD

The present invention relates to a magnetoresistive device and a magnetic memory.

### BACKGROUND ART

Giant magnetoresistive (GMR) elements composed of a multilayer film of ferromagnetic layers and non-magnetic layers and tunnel magnetoresistive (TMR) elements using an insulating layer (tunnel barrier layer, barrier layer) as a non-magnetic layer are known as magnetoresistive effect elements. The magnetoresistive effect element can be applied to a magnetic sensor, a high-frequency component, a magnetic head, an in-memory computing element, and a non-volatile random access memory (MRAM).

MRAM is a magnetic memory that integrates magnetoresistive effect elements. The MRAM reads and writes data by utilizing the property that when the magnetization directions of two ferromagnetic layers sandwiching a non-magnetic layer in a magnetoresistive effect element change, the resistance of the magnetoresistive effect element changes. The stored data can be rewritten by controlling the magnetization direction of the ferromagnetic layer of the magnetoresistive effect element. Spin-transfer torque and spin-orbit torque are examples of torques that act on the magnetization of the ferromagnetic layer. These torques act on the magnetization to control the magnetization direction in the ferromagnetic layer. Magnetic memories include MRAM, which stores digital data, as well as neuromorphic devices and spin memristors, which store analog data by mimicking the human brain.

Spin-transfer torque (STT) is generated by passing a current in a direction intersecting the plane in which the ferromagnetic layers extend (for example, in the stacking direction of the magnetoresistive effect element). The spin-orbit torque is induced by the spin current generated by the spin-orbit interaction or the Rashba effect at the interface of dissimilar materials. For example, Patent Document 1 discloses a magnetoresistive effect element that utilizes spin-orbit torque. Furthermore, Patent Document 1 describes that the effect of the external magnetic field on a magnetoresistive effect element can be reduced by arranging a soft magnetic material to surround the magnetoresistive effect element.

### CITATION LIST

### Patent Document

Patent Document 1: Japanese Unexamined Patent Application, First Publication No. 2020-35792

### SUMMARY OF INVENTION

### Technical Problem

The external magnetic field affects the magnetization of a ferromagnetic material. When the external magnetic field acts on the magnetoresistive effect element, the magnetization direction of the magnetoresistive effect element changes, and there is a risk that data may be rewritten. There is a need for a new structure that can reduce the effect of the external magnetic field on the magnetoresistive effect element.

The present invention has been made in view of the above circumstances, and has an object to provide a magnetoresistive device capable of reducing the effect of the external magnetic field on a magnetoresistive effect element.

### Solution to Problem

In order to solve the above problems, the present invention provides the following means.

A magnetoresistive device includes: a substrate; a first magnetoresistive effect element; a first layer sandwiched between the substrate and the first magnetoresistive effect element; and a second layer located at a position farther from the substrate than the first magnetoresistive effect element in a stacking direction. The first magnetoresistive effect element includes a stack, a spin-orbit torque wiring in contact with the stack, a first via wiring connected to the spin-orbit torque wiring, and a second via wiring connected to the spin-orbit torque wiring at a position different from the first via wiring. The stack includes a first ferromagnetic layer, a second ferromagnetic layer, and a non-magnetic layer sandwiched between the first ferromagnetic layer and the second ferromagnetic layer. The first layer or the second layer includes an insulating first magnetic layer.

### Advantageous Effects of Invention

The magnetoresistive device according to the present disclosure can reduce the effect of the external magnetic field.

### BRIEF DESCRIPTION OF DRAWINGS

FIG. 1 A circuit diagram of a magnetoresistive device according to a first embodiment.

FIG. 2 A cross-sectional view of characteristic parts of the magnetoresistive device according to the first embodiment.

FIG. 3 A cross-sectional view of a magnetoresistive effect element according to the first embodiment.

FIG. 4 A plan view of the magnetoresistive effect element according to the first embodiment.

FIG. 5 An enlarged view of characteristic parts of the magnetoresistive device according to the first embodiment.

FIG. 6 A cross-sectional view of characteristic parts of a magnetoresistive device according to a second embodiment.

FIG. 7 A cross-sectional view of characteristic parts of a magnetoresistive device according to a third embodiment.

FIG. 8 A cross-sectional view of characteristic parts of a magnetoresistive device according to a fourth embodiment,

FIG. 9 A cross-sectional view of characteristic parts of a magnetoresistive device according to a fifth embodiment.

FIG. 10 A cross-sectional view of characteristic parts of a magnetoresistive device according to a sixth embodiment.

FIG. 11 A plan view of characteristic parts of a magnetoresistive device according to a seventh embodiment.

FIG. 12 A plan view of characteristic parts of a first modified example of the magnetoresistive device according to the seventh embodiment.

FIG. 13 A plan view of characteristic parts of a second modified example of the magnetoresistive device according to the seventh embodiment.

FIG. 14 A cross-sectional view of characteristic parts of a magnetoresistive device according to an eighth embodiment.

FIG. 15 A cross-sectional view of characteristic parts of a magnetoresistive device according to a ninth embodiment.

### DESCRIPTION OF EMBODIMENTS

Hereinafter, this embodiment will be described in detail with reference to the drawings. The drawings used in the following description may show characteristic parts in an enlarged scale for the sake of convenience in order to make the characteristics easier to understand, and the dimensional ratios of each component may differ from the actual ones. The materials, dimensions, and the like exemplified in the following description are merely examples, and the present invention is not limited to them. They can be modified as appropriate within the scope of the effect of the present invention.

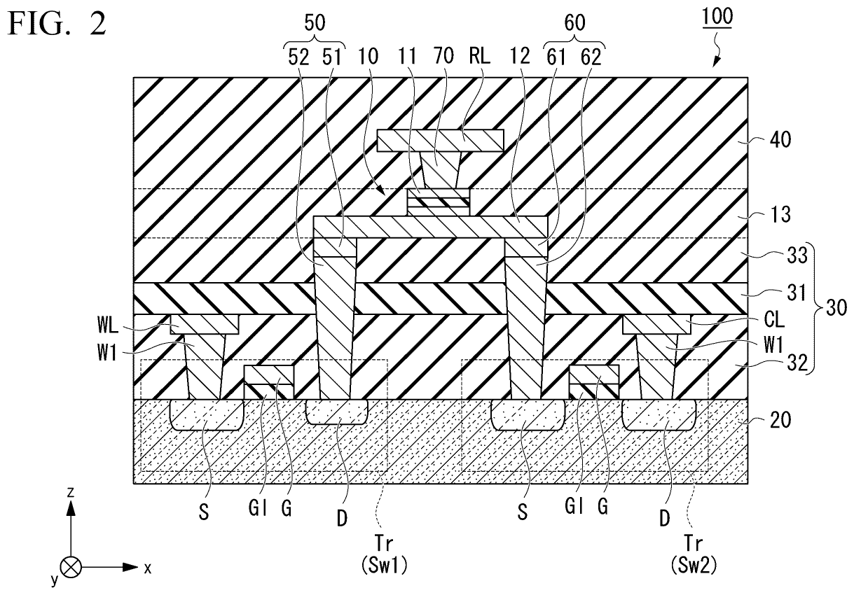

First, directions will be defined. One direction on one surface of a substrate 20 (see FIG. 2) described later is defined as an x direction, and a direction perpendicular to the x direction is defined as a y direction. The x direction is, for example, the longitudinal direction of a spin-orbit torque wiring 12. The z direction is perpendicular to the x and y directions and is the direction from the substrate 20 to a magnetoresistive effect element 10. The z direction is an example of a stacking direction in which each layer is stacked. Hereinafter, the +z direction may be expressed as “up” and the −z direction as “down.” Up and down do not necessarily match the direction of gravity.

In this specification, “extending in the x direction” means, for example, that the dimension in the x direction is larger than the smallest dimension among the dimensions in the x direction, the y direction, and the z direction. The same applies to the case of extending in the other directions.

### First Embodiment

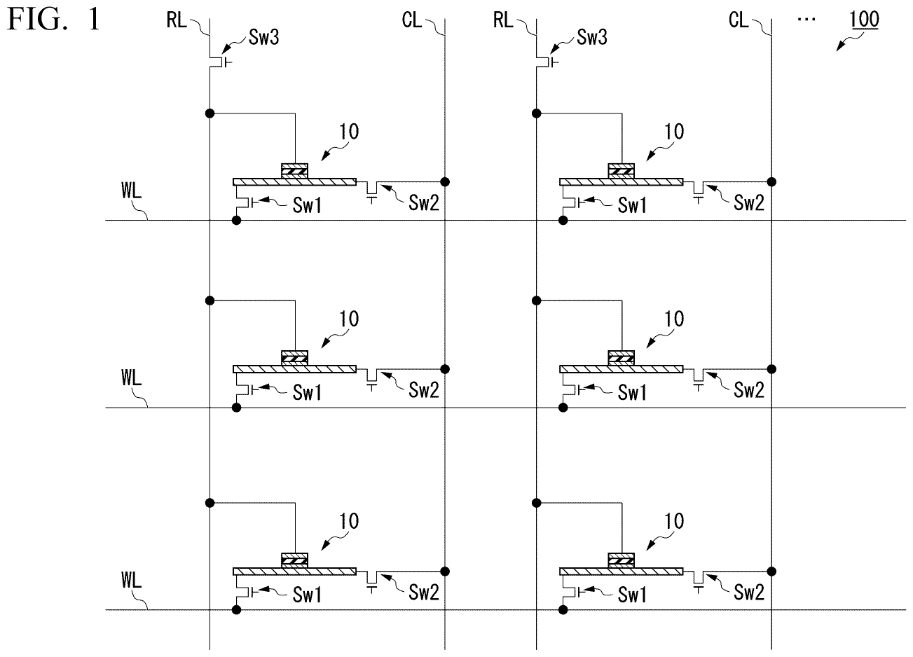

FIG. 1 is a circuit diagram of a magnetoresistive device 100 according to a first embodiment. The magnetoresistive device 100 includes a plurality of the magnetoresistive effect elements 10, a plurality of write wirings WL, a plurality of common wirings CL, a plurality of read wirings RL, a plurality of first switching elements Sw1, a plurality of second switching elements Sw2, and a plurality of third switching elements Sw3. The magnetoresistive device 100 has, for example, the magnetoresistive effect elements 10 arranged in a matrix. The magnetoresistive device 100 is, for example, a magnetic memory or the like.

Each of the write wirings WL electrically connects a power supply to one or more magnetoresistive effect elements 10. Each of the common wirings CL is used both when writing and reading data. Each of the common wiring CL electrically connects a reference potential to one or more magnetoresistive effect elements 10. The reference potential is, for example, ground. The common wiring CL may be provided for each of the plurality of magnetoresistive effect elements 10, or may be provided across the plurality of magnetoresistive effect elements 10. Each of the read wirings RL electrically connects a power supply to one or more magnetoresistive effect elements 10. The power supply is connected to the magnetoresistive device 100 in use.

Each of the magnetoresistive effect elements 10 is electrically connected to the first switching element Sw1, the second switching element Sw2, and the third switching element Sw3. The first switching element Sw1 is connected between the magnetoresistive effect element 10 and the write wiring WL. The second switching element Sw2 is connected between the magnetoresistive effect element 10 and the common wiring CL. The third switching element Sw3 is connected to the read wiring RL that spans the plurality of magnetoresistive effect elements 10.

When a predetermined first switching element Sw1 and a predetermined second switching element Sw2 are turned on, a write current flows between the write wiring WL and the common wiring CL connected to a predetermined magnetoresistive effect element 10. When a write current flows, data is written to a specific magnetoresistive effect element 10. When a predetermined second switching element Sw2 and a predetermined third switching element Sw3 are turned on, a read current flows between the common wiring CL and the read wiring RL connected to the predetermined magnetoresistive effect element 10. When a read current flows, data is read from a predetermined magnetoresistive effect element 10.

The first switching element Sw1, the second switching element Sw2, and the third switching element Sw3 are elements that control the flow of current. The first switching element Sw1, the second switching element Sw2, and the third switching element Sw3 are, for example, a transistor, elements that use a phase change of a crystal layer such as an Ovonic Threshold Switch (OTS), elements that use a change in band structure such as a Metal-Insulator Transition (MIT) switch, elements that use a breakdown voltage such as a Zener diode or an avalanche diode, or elements whose conductivity changes with a change in atomic position.

In the magnetoresistive device 100 shown in FIG. 1, the magnetoresistive effect elements 10 connected to the same read wiring RL share the third switching element Sw3. The third switching element Sw3 may be provided in each of the magnetoresistive effect elements 10. Further, the third switching element Sw3 may be provided for each magnetoresistive effect element 10, and the first switching element Sw1 or the second switching element Sw2 may be shared by the magnetoresistive effect elements 10 connected to the same wiring.

FIG. 2 is a cross-sectional view of characteristic parts of the magnetoresistive device 100 according to the first embodiment. FIG. 2 is a cross-section taken along an xz plane passing through the center of the width in the y direction of the spin-orbit torque wiring 12, which will be described later.

The magnetoresistive device 100 includes the magnetoresistive effect element 10, the substrate 20, a first layer 30, a second layer 40, a first via wiring 50, a second via wiring 60, and a third via wiring 70. The magnetoresistive effect element 10 is an example of the first magnetoresistive effect element.

The substrate 20 is, for example, a semiconductor substrate. The substrate 20 is provided with, for example, a transistor Tr. The transistor Tr is an example of the first switching element Sw1, the second switching element Sw2, and the third switching element Sw3. The transistor Tr is, for example, a field effect transistor, and has a gate electrode G, a gate insulating film GI, and a source S and a drain D formed on the substrate 20. The source S and drain D are determined by the direction of current flow and are both active regions. The positional relationship between the source S and the drain D may be reversed. The transistors Tr are arranged, for example, in a matrix on the surface of the substrate 20.

The magnetoresistive effect element 10 includes a stack 11 and the spin-orbit torque wiring 12. The magnetoresistive effect element 10 is covered with the insulating layer 13. The insulating layer 13 is at the same level as the magnetoresistive effect element 10 and covers the sidewalls of the magnetoresistive effect element 10. The insulating layer 13 is, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

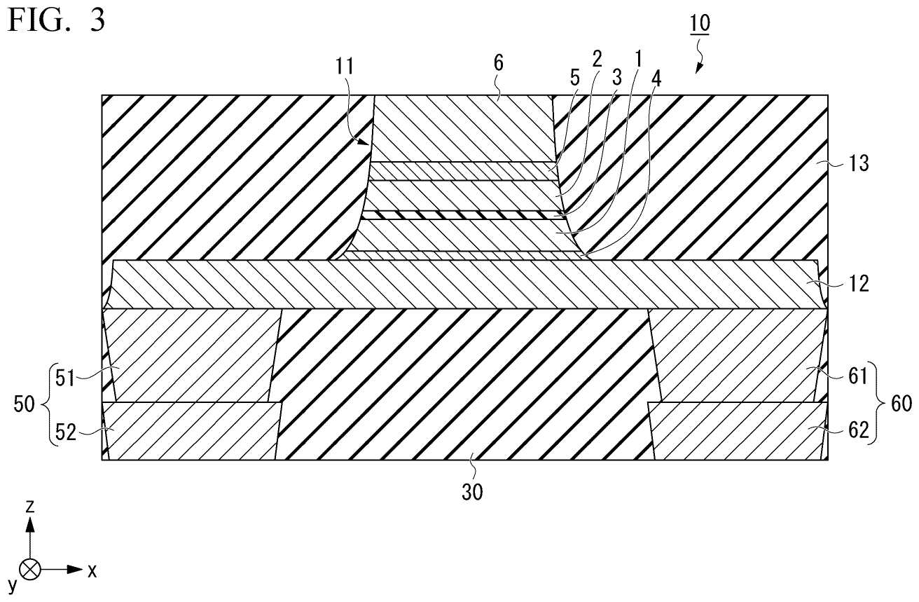

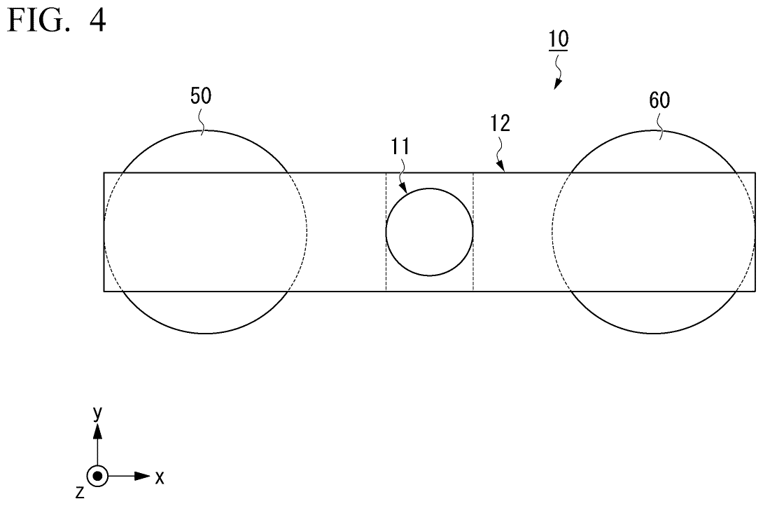

FIG. 3 is an enlarged view in the vicinity of the magnetoresistive effect element 10 according to the first embodiment. FIG. 3 is a cross-section of the magnetoresistive effect element 10 taken along the xz plane passing through the center of the width of the spin-orbit torque wiring 12 in the y direction. FIG. 4 is a plan view showing the magnetoresistive effect element 10 when viewed from the z direction.

The magnetoresistive effect element 10 is a magnetoresistive effect element that utilizes spin-orbit torque (SOT), and may be called a spin-orbit torque type magnetoresistive effect element, a spin injection type magnetoresistive effect element, or a spin current magnetoresistive effect element.

The magnetoresistive effect element 10 is an element for recording and storing data. The magnetoresistive effect element 10 records data by the resistance value of the stack 11 in the z direction. The resistance value in the z direction of the stack 11 changes when a write current is applied along the spin-orbit torque wiring 12 and spins are injected from the spin-orbit torque wiring 12 into the stack 11. The resistance value of the stack 11 in the z direction can be read by applying a read current to the stack 11 in the z direction.

The stack 11 is connected to the spin-orbit torque wiring 12. The stack 11 is, for example, stacked on the spin-orbit torque wiring 12. The positional relationship between the stack 11 and the spin-orbit torque wiring 12 in the z direction may be reversed, and the spin-orbit torque wiring 12 may be stacked on the stack 11, for example.

The stack 11 is a columnar body. The shape of the stack 11 in a plan view in the z direction is, for example, a circle, an ellipse, or a rectangle. The side surface of the stack 11 is, for example, inclined with respect to the z direction.

The stack 11 includes, for example, a first ferromagnetic layer 1, a second ferromagnetic layer 2, a non-magnetic layer 3, an underlayer 4, a cap layer 5, and a mask layer 6. The resistance value of the stack 11 changes according to the difference in the relative angle between the magnetizations of the first ferromagnetic layer 1 and the second ferromagnetic layer 2 sandwiching the non-magnetic layer 3 therebetween.

The first ferromagnetic layer 1 faces, for example, the spin-orbit torque wiring 12. The first ferromagnetic layer 1 may be directly in contact with the spin-orbit torque wiring 12 or indirectly in contact with the spin-orbit torque wiring 12 via the underlayer 4. The first ferromagnetic layer 1 is closer to the spin-orbit torque wiring 12 than the second ferromagnetic layer 2.

Spins are injected into the first ferromagnetic layer 1 from the spin-orbit torque wiring 12. The magnetization of the first ferromagnetic layer 1 is subjected to a spin-orbit torque (SOT) by the injected spins, and the orientation direction changes. The first ferromagnetic layer 1 is called a free magnetic layer.

The first ferromagnetic layer 1 contains a ferromagnetic material. The ferromagnetic material is, for example, a metal selected from the group consisting of Cr, Mn, Co, Fe, and Ni, an alloy containing one or more of these metals, or an alloy containing these metals and at least one of the elements B, C, and N. Examples of the ferromagnetic material include Co—Fe, Co—Fe—B, Ni—Fe, Co—Ho alloy, Sm—Fe alloy, Fe—Pt alloy, Co—Pt alloy, and CoCrPt alloy.

The first ferromagnetic layer 1 may contain a Heusler alloy. Heusler alloys contain intermetallic compounds with the chemical composition XYZ or X₂YZ. X is a transition metal element or a noble metal element of the Co, Fe, Ni, or Cu group on the periodic table, Y is a transition metal element or an element type of X of the Mn, V, Cr, or Ti group, and Z is a typical element of groups III to V. Examples of Heusler alloys include Co₂FeSi, Co₂FeGe, Co₂FeGa, Co₂MnSi, Co₂Mn₁₋ₐFeₐAl_{b}Si_{1-b}, and Co₂FeGe_{1-c}Ga_{c}. Heusler alloys have high spin polarizability.

The second ferromagnetic layer 2 faces the first ferromagnetic layer 1 with the non-magnetic layer 3 interposed therebetween. The second ferromagnetic layer 2 contains a ferromagnetic material. The magnetization of the second ferromagnetic layer 2 is less likely to change its orientation than the magnetization of the first ferromagnetic layer 1 when a predetermined external force is applied. The second ferromagnetic layer 2 is called a magnetization fixed layer or a magnetization reference layer. The magnetoresistive effect element 10 shown in FIG. 3 has a magnetization fixed layer located farther from the substrate 20 than the magnetization free layer, and is called a top pin structure. The magnetoresistive effect element 10 may have a bottom pin structure in which the magnetization fixed layer is closer to the substrate 20 than the magnetization free layer.

The material constituting the second ferromagnetic layer 2 is the same as the material constituting the first ferromagnetic layer 1. The first ferromagnetic layer 1 and the second ferromagnetic layer 2 may contain the same material or may be different materials.

The second ferromagnetic layer 2 may have a synthetic antiferromagnetic structure (SAF structure). The synthetic antiferromagnetic structure consists of two magnetic layers sandwiching a non-magnetic layer. The second ferromagnetic layer 2 may have two magnetic layers and a spacer layer sandwiched between them. The coercive force of the second ferromagnetic layer 2 increases due to the antiferromagnetic coupling between the two ferromagnetic layers. The ferromagnetic layer is, for example, IrMn, PtMn, or the like. The spacer layer contains, for example, at least one selected from the group consisting of Ru, Ir, and Rh.

The non-magnetic layer 3 is sandwiched between the first ferromagnetic layer 1 and the second ferromagnetic layer 2. The non-magnetic layer 3 contains a non-magnetic material. When the non-magnetic layer 3 is an insulator (in the case of a tunnel barrier layer), for example, Al₂O₃, SiO₂, MgO, or MgAl₂O₄ can be used as the material. In addition to these, materials in which a part of Al, Si, and Mg is replaced with Zn, Be, or the like can also be used. Among these, MgO and MgAl₂O₄ are materials that can realize coherent tunneling, and therefore can efficiently inject spins. When the non-magnetic layer 3 is formed of metal, the material may be Cu, Au, Ag, or the like, Furthermore, when the non-magnetic layer 3 is a semiconductor, Si, Ge, CuInSe₂, CuGaSe₂, Cu(In, Ga)Se₂, or the like can be used as the material.

The underlayer 4 is located, for example, between the first ferromagnetic layer 1 and the spin-orbit torque wiring 12. The underlayer 4 may not be provided.

The underlayer 4 includes, for example, a buffer layer and a seed layer. The buffer layer is a layer that reduces the lattice mismatch between different crystals. The seed layer enhances the crystallinity of the layer deposited on the seed layer. The seed layer is, for example, formed on the buffer layer.

The buffer layer is, for example, Ta (simple material), TaN (tantalum nitride), CuN (copper nitride), TIN (titanium nitride), NiAl (nickel aluminum), or the like. The seed layer is, for example, Pt, Ru, Zr, NiCr alloy, or NiFeCr.

The cap layer 5 is on the second ferromagnetic layer 2. The cap layer 5, for example, strengthens the magnetic anisotropy of the second ferromagnetic layer 2. The cap layer 5, for example, strengthens the perpendicular magnetic anisotropy of the second ferromagnetic layer 2. The cap layer 5 is formed of, for example, magnesium oxide, W, Ta, Mo, or the like. The thickness of the cap layer 5 is, for example, 0.5 nm or more and 5.0 nm or less.

The mask layer 6 is on the cap layer 5. The mask layer 6 is part of a hard mask used to process the stack 11 during manufacturing. The mask layer 6 also functions as an electrode. The mask layer 6 contains, for example, Al, Cu, Ta, Ti, Zr, NiCr, a nitride (for example, TiN, TaN, or SiN), or an oxide (for example, SiO₂).

The stack 11 may include layers other than the first ferromagnetic layer 1, the second ferromagnetic layer 2, the non-magnetic layer 3, the underlayer 4, the cap layer 5, and the mask layer 6.

The spin-orbit torque wiring 12 extends in the x direction, for example, such that the length in the x direction is longer than the length in the y direction when viewed from the z direction. The write current flows in the x direction along the spin-orbit torque wiring 12 between the first via wiring 50 and the second via wiring 60.

The spin-orbit torque wiring 12 generates a spin current by the spin Hall effect when a current flows, and injects spins into the first ferromagnetic layer 1. The spin-orbit torque wiring 12 applies, for example, a spin-orbit torque (SOT) sufficient to reverse the magnetization of the first ferromagnetic layer 1 to the magnetization of the first ferromagnetic layer 1.

The spin Hall effect is a phenomenon in which, when a current is passed through a material, a spin current is induced in a direction perpendicular to the direction of the current due to spin-orbit interaction. The spin Hall effect is common to the normal Hall effect in that the direction of a moving charge (electron) can be bent. In the normal Hall effect, the movement direction of charged particles moving in a magnetic field is bent by the Lorentz force. In contrast, the spin Hall effect allows the direction of spin movement to be bent simply by the movement of electrons (the flow of current) even in the absence of a magnetic field.

For example, when a current flows through the spin-orbit torque wiring 12, first spins polarized in one direction and second spins polarized in the opposite direction to the first spins are bent by the spin Hall effect in a direction perpendicular to the current flow direction. For example, the first spins polarized in the −y direction are bent from the x direction, which is the travel direction, to the +z direction, and the second spins polarized in the +y direction are bent from the x direction, which is the travel direction, to the-z direction.

In a non-magnetic material (a material that is not ferromagnetic), the number of electrons with first spins generated by the spin Hall effect is equal to the number of electrons with second spins. That is, the number of electrons with the first spins in the +z direction is equal to the number of electrons with the second spins in the −z direction. The first spins and the second spins flow in a direction that eliminates the uneven distribution of spins. In the movement of the first spins and the second spins in the z direction, the flow of charges cancels each other out, so the amount of current becomes zero. A spin current that is not accompanied by current is specifically called a pure spin current.

If the flow of electrons with the first spins is expressed as J_{↑}, the flow of electrons with the second spins as J_{↓}, and the spin current as Jₛ, Jₛ=J_{↑}−J_{↓}. The spin current Jₛ is generated in the z direction. The first spins are injected from the spin-orbit torque wiring 12 into the first ferromagnetic layer 1.

The spin-orbit torque wiring 12 contains any one of a metal, an alloy, an intermetallic compound, a metal boride, a metal carbide, a metal silicide, a metal phosphide, and a metal nitride, which has a function of generating a spin current by the spin Hall effect when a write current flows. The spin-orbit torque wiring 12 contains, for example, any material selected from the group consisting of heavy metals having an atomic number of 39 or more, metal oxides, metal nitrides, metal oxynitrides, and topological insulators.

The spin-orbit torque wiring 12 contains, for example, a non-magnetic heavy metal as a main component. Heavy metals refer to metals with a specific gravity equal to or larger than that of yttrium (Y). The non-magnetic heavy metals are, for example, non-magnetic metals with a large atomic number of 39 or more that have d electrons or f electrons in their outermost shell. The spin-orbit torque wiring 12 is formed of, for example, Hf, Ta, and W. The non-magnetic heavy metals have stronger spin-orbit interactions than other metals. The spin Hall effect is generated by spin-orbit interaction, and spins tend to be unevenly distributed in the spin-orbit torque wiring 12. Accordingly, it becomes easier for a spin current Jₛ to be generated.

The spin-orbit torque wiring 12 may further contain a magnetic metal. The magnetic metal is a ferromagnetic metal or an antiferromagnetic metal. A small amount of magnetic metal contained in a non-magnetic material acts as a scattering factor for spins. The small amount is, for example, 3% or less of the total molar ratio of the elements constituting the spin-orbit torque wiring 12. When spins are scattered by a magnetic metal, the spin-orbit interaction is strengthened to thereby increase the efficiency of generating a spin current in response to a current.

The spin-orbit torque wiring 12 may contain a topological insulator. The topological insulator is a material in which the interior is an insulator or highly resistive material, but a spin-polarized metallic state exists on the surface. The topological insulators have internal magnetic fields due to spin-orbit interactions. The topological insulators exhibit new topological phases due to the effect of spin-orbit interactions even in the absence of an external magnetic field. The topological insulators can generate pure spin currents with high efficiency due to strong spin-orbit interaction and broken inversion symmetry at the edges.

Examples of topological insulators include SnTe, Bi_{1.5}Sb_{0.5}Te_{1.7}Se_{1.3}, TlBiSe₂, Bi₂Te₃, Bi₁₋ₓSbₓ, (Bi₁₋ₓSbₓ)₂Te₃, and the like. Topological insulators are capable of generating spin currents with high efficiency.

The spin-orbit torque wiring 12 is not limited to a single layer, but may be a stack of multiple layers. The spin-orbit torque wiring 12 may have, for example, a plurality of heavy metal layers and an insertion layer sandwiched between the heavy metal layers.

The first layer 30 is sandwiched between the substrate 20 and the magnetoresistive effect element 10. The first layer 30 is an interlayer insulating film that provides insulation between the substrate 20 and the magnetoresistive effect element 10.

The first layer 30 includes, for example, a magnetic layer 31, a first insulating layer 32, and a second insulating layer 33. The magnetic layer 31 is an example of the first magnetic layer.

The magnetic layer 31 extends in a layer shape, for example, in an xy plane. The magnetic layer 31 suppresses the effect of the external magnetic field on the magnetoresistive effect element 10.

The magnetic layer 31 contains an insulating magnetic material. Since the magnetic layer 31 is an insulator, the occurrence of current leakage and the like can be suppressed. Furthermore, when a metal magnetic material is annealed, the elements may diffuse, which may adversely affect the semiconductor circuit and the magnetoresistive effect element. In the insulating magnetic material, a compound is already formed, and the elements are unlikely to diffuse.

The magnetic layer 31 contains, for example, an oxide. The oxide contains, for example, at least a magnetic element and oxygen. The oxide is, for example, ferrite. Ferrite contains, for example, one or more atoms selected from the group consisting of Mn, Zn, Ni, Cu, Ba, Sr, Pb, and Co as well as Fe and O.

The first insulating layer 32 is located between the substrate 20 and the magnetic layer 31. If the substrate 20 on which the semiconductor element is formed is in direct contact with the magnetic layer 31, the magnetic field from the magnetic layer 31 may adversely affect the semiconductor element. By sandwiching the first insulating layer 32 between the substrate 20 and the magnetic layer 31, this effect can be suppressed. The first insulating layer 32 can be formed of, for example, the same material as the insulating layer 13.

The second insulating layer 33 is located between the magnetic layer 31 and the magnetoresistive effect element 10. By sandwiching the second insulating layer 33 between the magnetic layer 31 and the magnetoresistive effect element 10, the effect of a magnetic field from the magnetic layer 31 on the magnetoresistive effect element 10 can be suppressed. The second insulating layer 33 can be formed of, for example, the same material as the insulating layer 13.

The second layer 40 is located at a position farther from the substrate 20 than the magnetoresistive effect element 10 in the z direction. The second layer 40 extends in a layer shape in the xy plane. The second layer 40 covers the upper portion of the magnetoresistive effect element 10. The second layer 40 is an insulating layer and can be formed of, for example, the same material as the insulating layer 13.

The first via wiring 50 is connected to the spin-orbit torque wiring 12 of the magnetoresistive effect element 10. The first via wiring 50 penetrates, for example, the magnetic layer 31 in the z direction. The first via wiring 50 is a wiring that electrically connects the transistor Tr (first switching element Sw1) and the magnetoresistive effect element 10.

The first via wiring 50 is a columnar body. The first via wiring 50 may be a stack of a plurality of columnar bodies. The columnar body is, for example, a circular cylinder, an elliptical cylinder, or a rectangular cylinder.

The first via wiring 50 includes, for example, an electrode 51 and a wiring 52.

The electrode 51 is in contact with the spin-orbit torque wiring 12. The electrode 51 may contain, for example, a metal or alloy containing W, Ta, Ru, or Co, or a nitride of Ti, V, Cr, Zr, Nb, Mo, Ta, or W.

These elements are difficult to diffuse. Cu, Al, and the like used in the wiring 52 are easily diffused elements, and when they diffuse into the spin-orbit torque wiring 12, the characteristics of the spin-orbit torque wiring 12 are degraded. If the electrode 51 is provided between the wiring 52 and the spin-orbit torque wiring 12, electromigration from the wiring 52 to the spin-orbit torque wiring 12 can be suppressed.

In addition, the above materials are relatively hard materials. Therefore, when the surfaces of the second insulating layer 33 and the electrode 51 are planarized by chemical mechanical polishing (CMP), a flat surface is easily formed. The spin-orbit torque wiring 12 is formed on the second insulating layer 33 and the electrode 51. If this surface is flat, the spin-orbit torque wiring 12 becomes flat, and the efficiency of spin injection from the spin-orbit torque wiring 12 to the first ferromagnetic layer 1 increases.

The wiring 52 extends from the electrode 51 in the z direction. The wiring 52 contains a material having electrical conductivity. The wiring 52 is formed of, for example, Cu, Al, or the like.

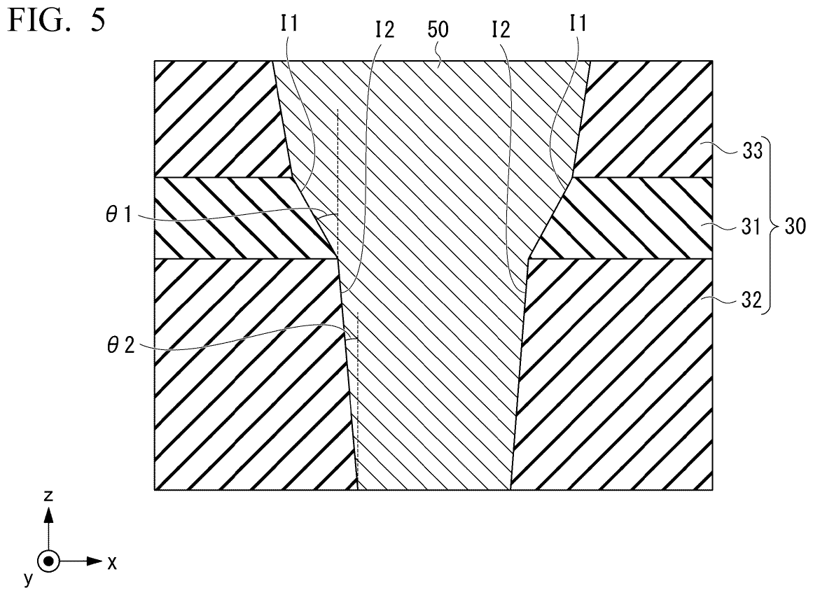

FIG. 5 is an enlarged view of characteristic parts of the magnetoresistive device 100 according to the first embodiment. FIG. 5 is an enlarged view in the vicinity of the magnetic layer 31 of the first via wiring 50.

The first via wiring 50 penetrates the first layer 30. An interface I1 between the first via wiring 50 and the magnetic layer 31 is inclined with respect to the z direction. In addition, an interface 12 between the first via wiring 50 and the first insulating layer 32 is inclined with respect to the z direction. An inclination angle θ1 of the interface I1 with respect to the z direction is, for example, larger than an inclination angle θ2 of the interface 12 with respect to the z direction. When the inclination angle θ1 of the interface I1 with respect to the z direction is large, the volume of the magnetic layer 31 on the side closer to the substrate 20 can be increased. Since the external magnetic field is irradiated to the magnetoresistive effect element 10 from the substrate 20, for example, the effect of the external magnetic field on the magnetoresistive effect element 10 can be reduced by increasing the volume of the magnetic layer 31 on the side of the substrate 20.

The second via wiring 60 is connected to the spin-orbit torque wiring 12 of the magnetoresistive effect element 10 at a position different from the first via wiring 50. The second via wiring 60 is located at a position sandwiching the first ferromagnetic layer 1 together with the first via wiring 50 when viewed from the z direction. The second via wiring 60 is connected to, for example, the same surface of the spin-orbit torque wiring 12 as the surface to which the first via wiring 50 is connected. The second via wiring 60 penetrates, for example, the magnetic layer 31 in the z direction. The second via wiring 60 is a wiring that electrically connects the transistor Tr (first switching element Sw2) and the magnetoresistive effect element 10.

The second via wiring 60 is a columnar body. The second via wiring 60 may be a stack of a plurality of columnar bodies. The columnar body is, for example, a circular cylinder, an elliptical cylinder, or a rectangular cylinder.

The second via wiring 60 has, for example, an electrode 61 and a wiring 62.

The electrode 61 is in contact with the spin-orbit torque wiring 12. The electrode 61 may be formed of, for example, a metal or alloy containing W, Ta, Ru, or Co, or a nitride of Ti, V, Cr, Zr, Nb, Mo, Ta, or W. The electrode 61 suppresses electromigration from the wiring 62 to the spin-orbit torque wiring 12.

The wiring 62 extends from the electrode 61 in the z direction. The wiring 62 contains a material having electrical conductivity. The wiring 62 is formed of, for example, Cu, Al, or the like.

The second via wiring 60 penetrates the first layer 30. The inclination angle θ1 of the interface between the second via wiring 60 and the magnetic layer 31 in the z direction is larger than, for example, the inclination angle θ2 of the interface between the first via wiring 50 and the first insulating layer 32 with respect to the z direction.

The third via wiring 70 is connected to the stack 11. When data is read from the magnetoresistive effect element 10, a read current flows through the third via wiring 70. The third via wiring 70 contains a material having electrical conductivity.

Subsequently, a method for manufacturing the magnetoresistive device 100 will be described. The magnetoresistive device 100 is formed by a process of stacking each layer and a process of processing a part of each layer into a predetermined shape. The layers can be stacked by sputtering, chemical vapor deposition (CVD), electron beam deposition (EB deposition), atomic laser deposition, and the like. The layers can be processed by photolithography and the like.

For example, the first layer 30 is formed by sequentially stacking the first insulating layer 32, the magnetic layer 31, and the second insulating layer 33 on the substrate 20 provided with the transistor Tr. Subsequently, openings are formed in the first layer 30 and the openings are filled with a conductor to form the first via wiring 50 and the second via wiring 60.

Subsequently, the surfaces of the first layer 30, the first via wiring 50, and the second via wiring 60 are chemically and mechanically polished. When the first via wiring 50 has the electrode 51, the step at the boundary between the electrode 51 and the first layer 30 becomes smaller. Furthermore, when the second via wiring 60 has the electrode 61, the step at the boundary between the electrode 61 and the first layer 30 becomes smaller.

Subsequently, a layer to become the spin-orbit torque wiring, a layer to become the first ferromagnetic layer 1, a layer to become the non-magnetic layer 3, and a layer to become the second ferromagnetic layer 2 are stacked in this order on the first layer 30. Then, these layers are processed into a predetermined shape to form the magnetoresistive effect element 10 including the stack 11 and the spin-orbit torque wiring 12. Subsequently, the insulating layer 13 is coated to cover the magnetoresistive effect element 10. Subsequently, the surface of the insulating layer 13 is chemically and mechanically polished to expose the surface of the stack 11.

Subsequently, the second layer 40 is formed on the surfaces of the insulating layer 13 and the stack 11. Moreover, openings are formed in the second layer 40 and filled with a conductor to form the third via wiring 70, the read wiring RL, and the like. By using this procedure, the magnetoresistive device 100 according to this embodiment can be manufactured.

Since the magnetoresistive device 100 according to the first embodiment includes the magnetic layer 31, the effect of the external magnetic field on the magnetoresistive effect element 10 can be reduced. In particular, since the spin-orbit torque is easily affected by external magnetic fields, environmental temperature, and the like, the effect of having the magnetic layer 31 is significant. Furthermore, since the magnetic layer 31 is formed of an insulating magnetic material, current leakage from the semiconductor circuit and the magnetoresistive effect element 10 to the magnetic layer 31 can be suppressed. Furthermore, since the magnetic layer 31 is formed of an insulating magnetic material, element diffusion from the magnetic layer 31 can be suppressed.

### Second Embodiment

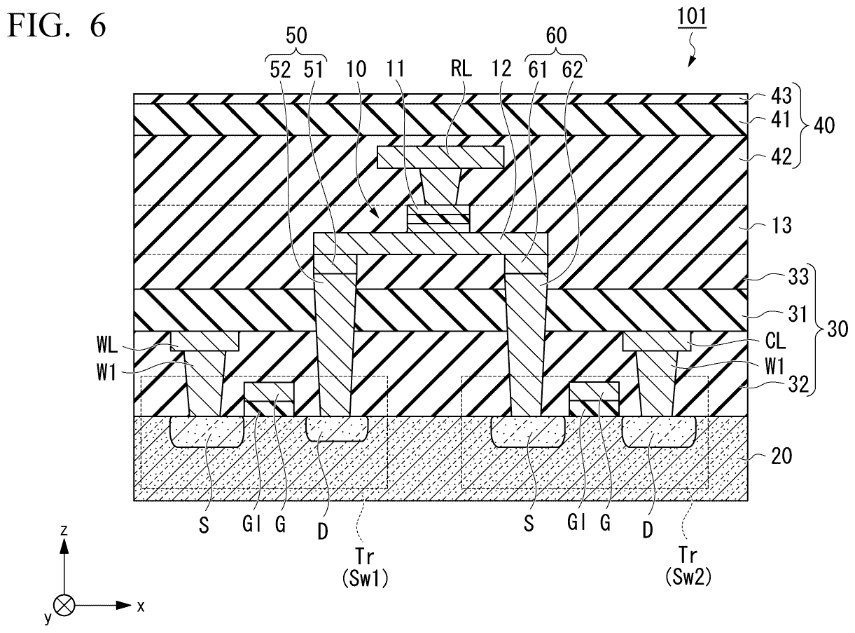

FIG. 6 is a cross-sectional view of a magnetoresistive device 101 according to a second embodiment. The magnetoresistive device 101 according to the second embodiment is different from the magnetoresistive device 100 according to the first embodiment in the configuration of the second layer 40. In the magnetoresistive device 101 according to the second embodiment, the same components as those in the magnetoresistive device 100 are denoted by the same reference numerals and will not be described.

The second layer 40 includes a magnetic layer 41, a first insulating layer 42, and a second insulating layer 43. The magnetic layer 41 of the second embodiment is an example of the second magnetic layer.

The magnetic layer 41 extends in a layer shape, for example, in the xy plane. The magnetic layer 41 suppresses the effect of the external magnetic field on the magnetoresistive effect element 10. The magnetic layer 41 contains an insulating magnetic material. The magnetic layer 41 contains, for example, an oxide. The oxide contains, for example, at least a magnetic element and oxygen. The oxide is, for example, ferrite. The ferrite contains, for example, one or more atoms selected from the group consisting of Mn, Zn, Ni, Cu, Ba, Sr, Pb, and Co as well as Fe and O.

The first insulating layer 42 is located between the magnetoresistive effect element 10 and the magnetic layer 41. The second insulating layer 43 is located at a position far from the substrate 20 of the magnetic layer 41. The first insulating layer 42 and the second insulating layer 43 can be formed of, for example, the same material as the insulating layer 13.

In the magnetoresistive device 101 according to the second embodiment, since the magnetoresistive effect element 10 is sandwiched between the magnetic layer 31 and the magnetic layer 41, the effect of the external magnetic field on the magnetoresistive effect element 10 can be further reduced.

### Third Embodiment

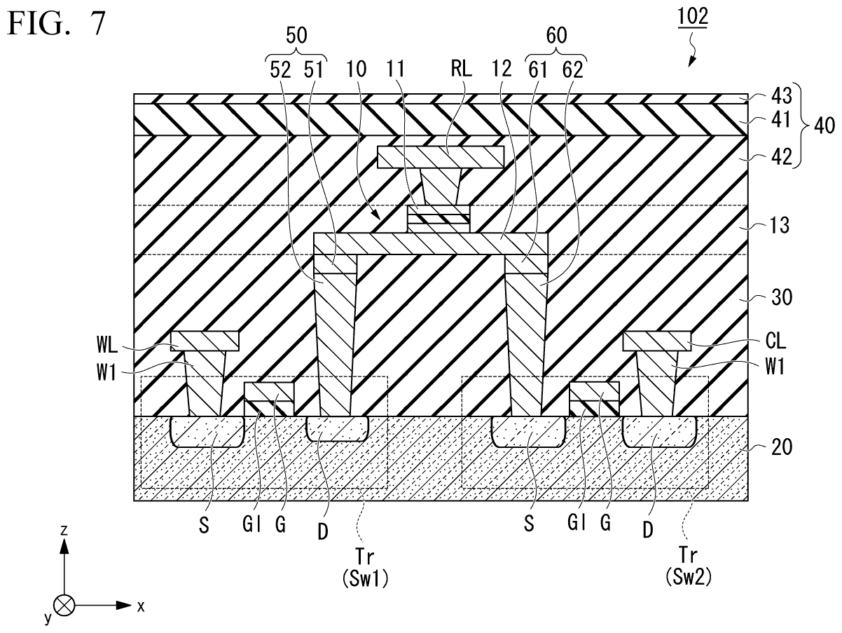

FIG. 7 is a cross-sectional view of a magnetoresistive device 102 according to a third embodiment. The magnetoresistive device 102 according to the third embodiment is different from the magnetoresistive device 100 according to the first embodiment in the configurations of the first layer 30 and the second layer 40. In the magnetoresistive device 102 according to the third embodiment, the same components as those in the magnetoresistive device 100 are denoted by the same reference numerals and will not be described.

The first layer 30 of the magnetoresistive device 102 consists of a single insulating layer extending in the xy plane. The first layer 30 can be formed of, for example, the same material as the insulating layer 13.

The second layer 40 includes a magnetic layer 41, a first insulating layer 42, and a second insulating layer 43. The magnetic layer 41 of the third embodiment is an example of the first magnetic layer. The configurations of the magnetic layer 41, the first insulating layer 42, and the second insulating layer 43 are the same as those of the magnetoresistive device 101 according to the second embodiment.

Since the magnetoresistive device 102 according to the third embodiment includes the magnetic layer 41, the effect of the external magnetic field on the magnetoresistive effect element 10 can be reduced.

### Fourth Embodiment

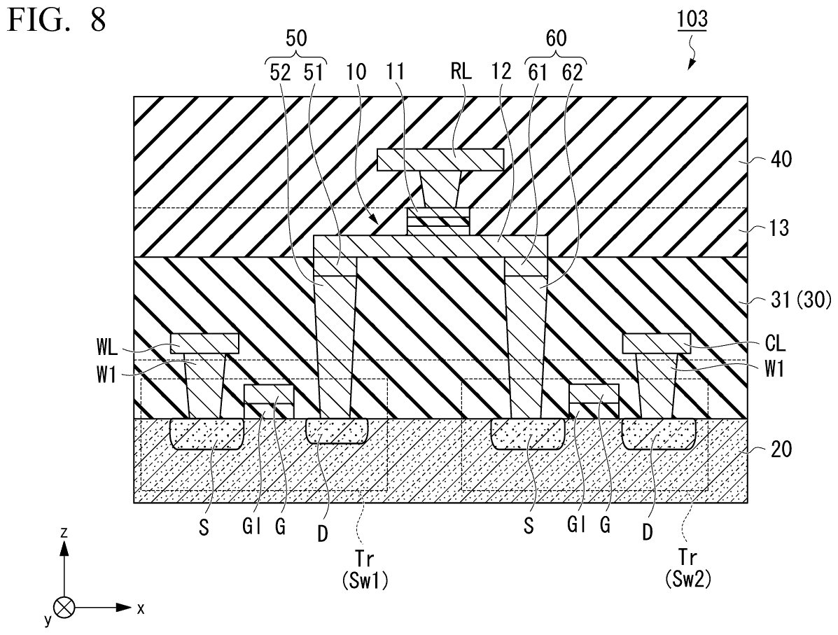

FIG. 8 is a cross-sectional view of a magnetoresistive device 103 according to a fourth embodiment. The magnetoresistive device 103 according to the fourth embodiment is different from the magnetoresistive device 100 according to the first embodiment in the configuration of the first layer 30. In the magnetoresistive device 103 according to the fourth embodiment, the same components as those in the magnetoresistive device 100 are denoted by the same reference numerals and will not be described.

The first layer 30 of the magnetoresistive device 103 consists of a single magnetic layer 31 extending in the xy plane. Since the magnetic layer 31 has insulating properties, even a single layer can function as an interlayer insulating film.

The magnetoresistive device 103 according to the fourth embodiment has the same effect as the magnetoresistive device 100 according to the first embodiment.

### Fifth Embodiment

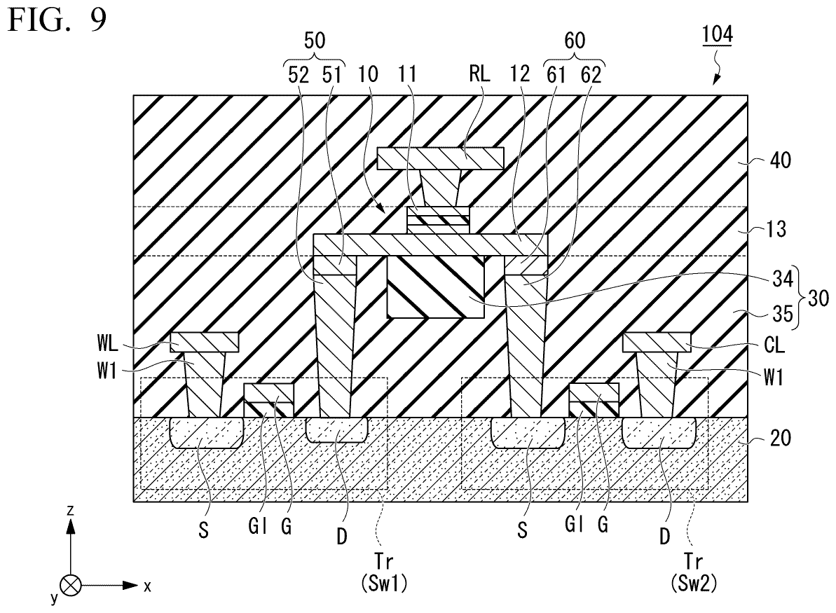

FIG. 9 is a cross-sectional view of a magnetoresistive device 104 according to a fifth embodiment. The magnetoresistive device 104 according to the fifth embodiment is different from the magnetoresistive device 100 according to the first embodiment in the configuration of the first layer 30. In the magnetoresistive device 104 according to the fifth embodiment, the same components as those in the magnetoresistive device 100 are denoted by the same reference numerals and will not be described.

The first layer 30 of the magnetoresistive device 104 includes a magnetic layer 34 and an insulating layer 35. The magnetic layer 34 is an example of the first magnetic layer. The magnetic layer 34 is formed of the same material as the magnetic layer 31. The insulating layer 35 is formed of the same material as the insulating layer 13.

The magnetic layer 34 is located between the first via wiring 50 and the second via wiring 60 when viewed from the z direction. The magnetic layer 34 is located at, for example, a position overlapping the stack 11 when viewed from the z direction. The insulating layer 35 coats the periphery of the magnetic layer 34.

The first ferromagnetic layer 1 of the stack 11 is particularly susceptible to the effect of the external magnetic field. By providing the magnetic layer 34 to block the external magnetic field at a pinpoint where the effect of the external magnetic field is large, the magnetoresistive device 104 can reduce the effect of the external magnetic field. Furthermore, by providing the magnetic layer 34 at a pinpoint, it is possible to suppress a decrease in the integration of the magnetoresistive device 104 that is caused by the formation of the magnetic layer 34.

The magnetoresistive device 104 according to the fifth embodiment has the same effect as the magnetoresistive device 100 according to the first embodiment.

### Sixth Embodiment

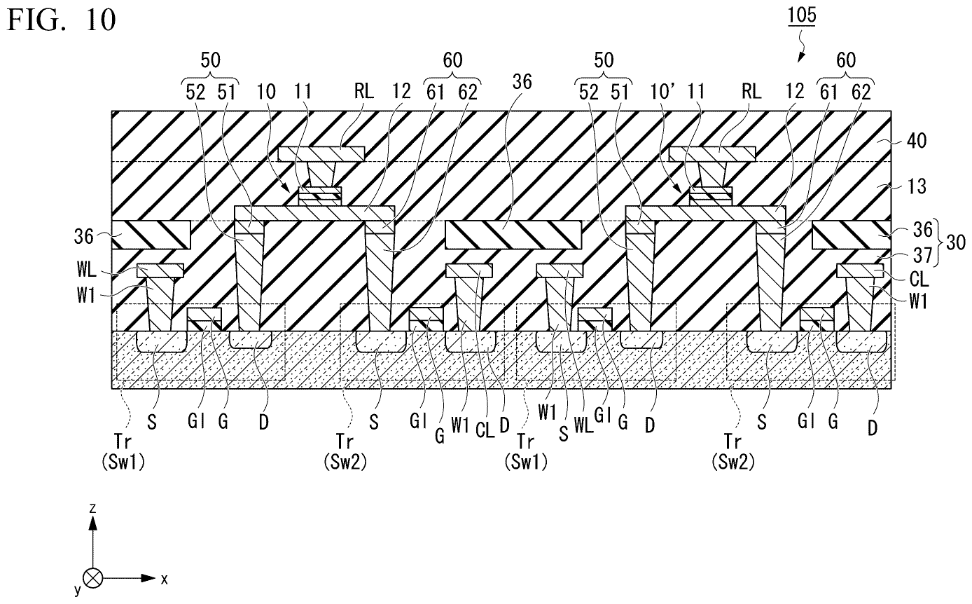

FIG. 10 is a cross-sectional view of a magnetoresistive device 105 according to a sixth embodiment. The magnetoresistive device 105 according to the sixth embodiment is different from the magnetoresistive device 100 according to the first embodiment in that a magnetoresistive effect element 10′ is further provided. Further, the magnetoresistive device 105 according to the sixth embodiment is also different from the magnetoresistive device 100 according to the first embodiment in the configuration of the first layer 30. In the magnetoresistive device 105 according to the sixth embodiment, the same components as those in the magnetoresistive device 100 are denoted by the same reference numerals and will not be described.

The magnetoresistive device 105 includes another magnetoresistive effect element 10′ in addition to the magnetoresistive effect element 10. The magnetoresistive effect element 10′ has the same configuration as the magnetoresistive effect element 10, and includes the stack 11 and the spin-orbit torque wiring 12. The magnetoresistive effect element 10′ is located at the same layer as the magnetoresistive effect element 10. The first via wiring 50 and the second via wiring 60 are connected to the magnetoresistive effect element 10′. The magnetoresistive effect element 10′ is adjacent to, for example, the magnetoresistive effect element 10 in the x direction. The magnetoresistive effect element 10′ may be adjacent to the magnetoresistive effect element 10 in the y direction.

The first layer 30 of the magnetoresistive device 105 includes a magnetic layer 36 and an insulating layer 37. The magnetic layer 36 is an example of the first magnetic layer. The magnetic layer 36 is formed of the same material as the magnetic layer 31. The insulating layer 37 is formed of the same material as the insulating layer 13.

The magnetic layer 36 is located between the magnetoresistive effect element 10 and the magnetoresistive effect element 10′ when viewed from the z direction.

The magnetoresistive device 105 according to the sixth embodiment has the same effect as the magnetoresistive device 100 according to the first embodiment.

Furthermore, the presence of the magnetic layer 36 between adjacent elements can reduce the effect of the magnetic field between the adjacent elements.

### Seventh Embodiment

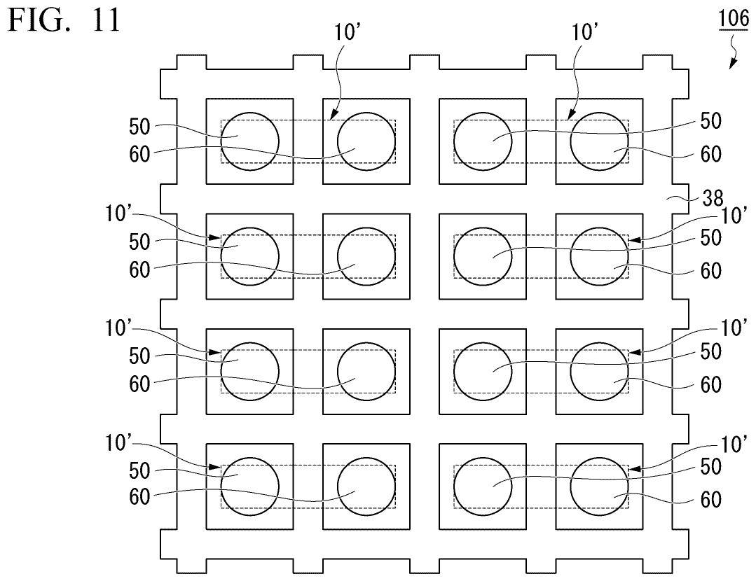

FIG. 11 is a plan view of a magnetoresistive device 106 according to a seventh embodiment. The magnetoresistive device 106 according to the seventh embodiment is different from the magnetoresistive device 105 according to the sixth embodiment in the configuration of the first layer 30. In the magnetoresistive device 106 according to the seventh embodiment, the same components as those in the magnetoresistive device 105 are denoted by the same reference numerals and will not be described.

In the magnetoresistive device 106, a magnetic layer 38 of the first layer 30 has a different shape from the magnetic layer 36 of the magnetoresistive device 105. The magnetic layer 38 is an example of the first magnetic layer. The first layer 30 includes the magnetic layer 38.

The magnetic layer 38 surrounds the periphery of each of the first via wiring 50 and the second via wiring 60 when viewed from the z direction. The magnetic layer 38 is formed of the same material as the magnetic layer 31.

The magnetoresistive device 106 according to the seventh embodiment has the same effect as the magnetoresistive device 100 according to the first embodiment.

Further, the magnetoresistive device 106 can form a magnetic flux in a circular shape along the magnetic layer 38, and can further suppress the effect of the external magnetic field on the magnetoresistive effect element 10.

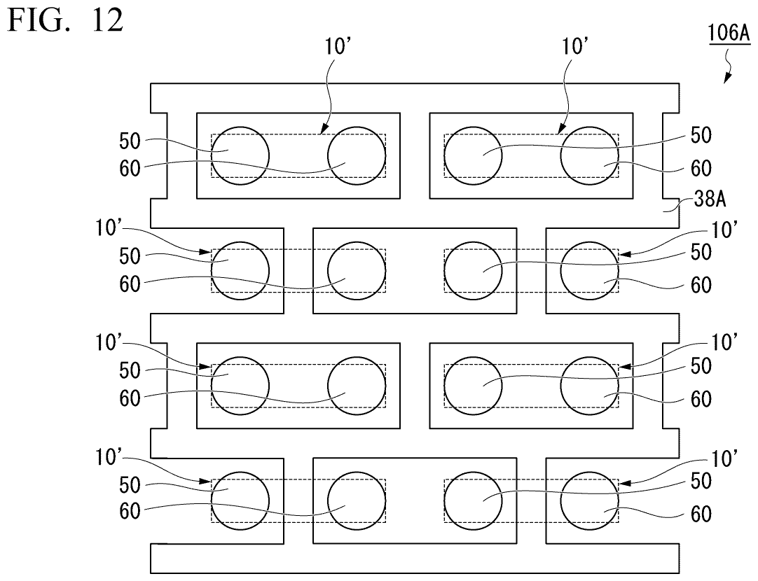

Further, FIG. 12 is a plan view of a magnetoresistive device 106A according to a first modified example of the seventh embodiment. A magnetic layer 38A shown in FIG. 12 surrounds the periphery of a pair of the first via wiring 50 and the second via wiring 60 when viewed from the z direction. The pair of the first via wiring 50 and the second via wiring 60 may be a pair that is connected to the same spin-orbit torque wiring 12, or a pair that is not connected to the same spin-orbit torque wiring 12. Further, the magnetic layer 38A may surround the periphery of two or more via wirings (the first via wirings 50 or the second via wirings 60). The magnetoresistive device 106A according to the first modified example can also form a magnetic flux in a circular shape along the magnetic layer 38A, and can further suppress the effect of the external magnetic field on the magnetoresistive effect element 10.

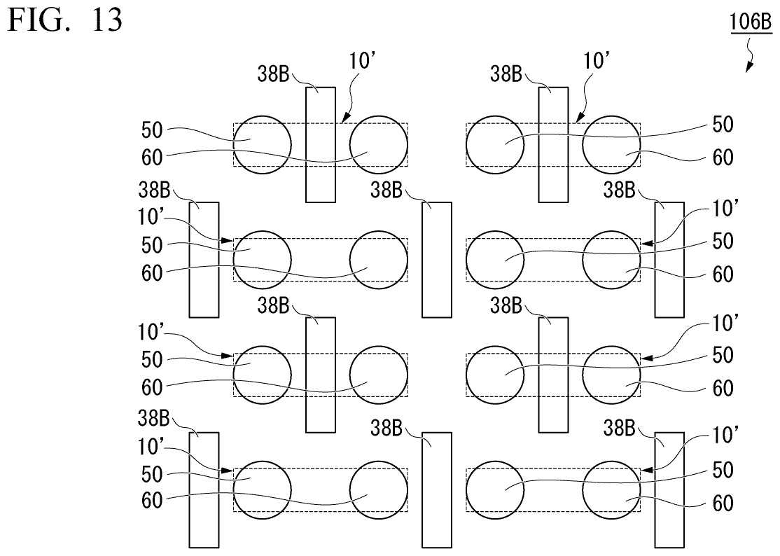

Further, FIG. 13 is a plan view of a magnetoresistive device 106B according to a second modified example of the seventh embodiment. A plurality of magnetic layers 38B shown in FIG. 13 are provided. The magnetic layer 38B is located between the first via wiring 50 and the second via wiring 60 of each magnetoresistive effect element 10′ belonging to a first column and between the magnetoresistive effect elements 10′ belonging to a second column when viewed from the z direction.

The magnetic layers 38B are not connected to each other, but can form a circular magnetic flux. Therefore, the magnetoresistive device 106B according to the second modified example can further suppress the effect of the external magnetic field on the magnetoresistive effect element 10. In addition, the position of the magnetic layer 38B is shifted for each column of the magnetoresistive effect elements arranged in a matrix.

By arranging the magnetic layer 38B, which is a structural body, at an effective position, it is possible to suppress a decrease in the integration of the magnetoresistive device 106B.

### Eighth Embodiment

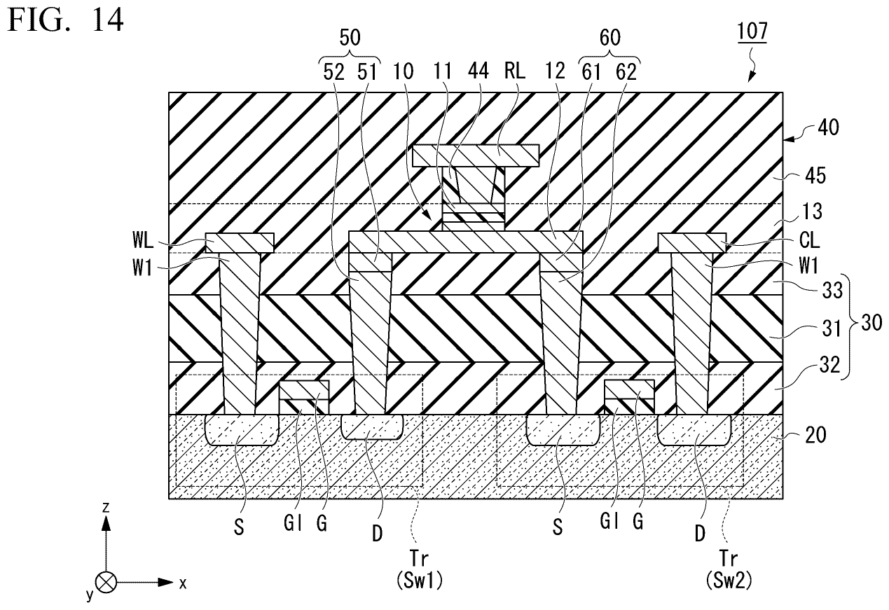

FIG. 14 is a cross-sectional view of a magnetoresistive device 107 according to an eighth embodiment. The magnetoresistive device 107 according to the eighth embodiment is different from the magnetoresistive device 102 according to the third embodiment in the configuration of the second layer 40. In the magnetoresistive device 107 according to the eighth embodiment, the same components as those in the magnetoresistive device 102 are denoted by the same reference numerals and will not be described.

The second layer 40 includes a magnetic layer 44 and an insulating layer 45. The magnetic layer 44 of the eighth embodiment is an example of the first magnetic layer.

The magnetic layer 44 coats, for example, the periphery of the third via wiring 70. The magnetic layer 44 is formed of the same material as the magnetic layer 41.

The insulating layer 45 covers the periphery of the magnetic layer 44. The insulating layer 45 is formed of, for example, the same material as the insulating layer 13.

The magnetoresistive device 107 according to the eighth embodiment has the same effect as the magnetoresistive device 100 according to the first embodiment.

Furthermore, the magnetic layer 44 suppresses the effect of the external magnetic field on the magnetoresistive effect element 10, and reduces the magnetic field generated from the third via wiring 70 when a current flows through the third via wiring 70.

### Ninth Embodiment

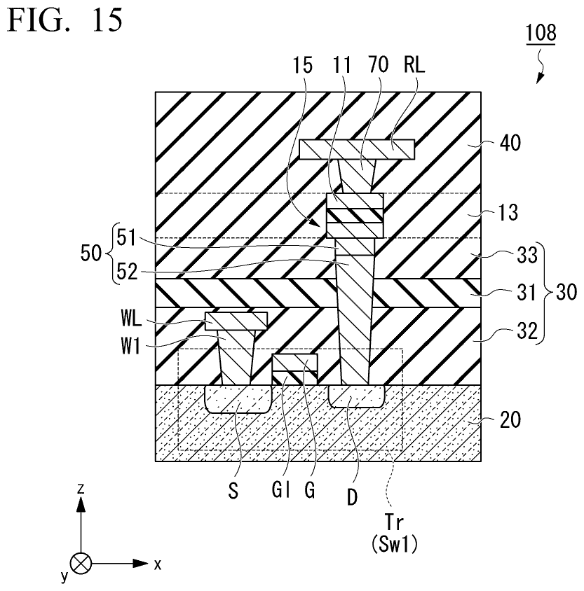

FIG. 15 is a cross-sectional view of a magnetoresistive device 108 according to a ninth embodiment. In the magnetoresistive device 108 according to the ninth embodiment, the same components as those in the magnetoresistive device 100 are denoted by the same reference numerals and will not be described.

The magnetoresistive device 108 includes a magnetoresistive effect element 15, the substrate 20, the first layer 30, the second layer 40, the first via wiring 50, and the third via wiring 70.

The magnetoresistive effect element 15 consists of the stack 11. The magnetoresistive effect element 15 is a spin-transfer torque type magnetoresistive effect element in which the orientation direction of the magnetization of the first ferromagnetic layer 1 changes due to spin-transfer torque. The spin-transfer torque type magnetoresistive effect element is a two-terminal type element that passes a current in the stacking direction of the stack 11 during both writing and reading. Therefore, the magnetoresistive device 108 does not include the second via wiring 60 and the second switching element Sw2.

Since the magnetoresistive device 108 according to the ninth embodiment includes the magnetic layer 31, it is possible to reduce the effect of the external magnetic field on the magnetoresistive effect element 15. Although spin-transfer torque type magnetoresistive effect elements are less susceptible to the external magnetic field than the spin-orbit torque type magnetoresistive effect elements, they are still susceptible to the effect of the external magnetic field. Therefore, even when the magnetoresistive effect element is a spin-transfer torque type magnetoresistive effect element, reducing the influence of the external magnetic field contributes to improving the reliability of the magnetoresistive device 108.

Although the preferred aspects of the present invention have been illustrated by way of some embodiments, the present invention is not limited to these embodiments. For example, the characteristic configurations of each embodiment may be applied to the other embodiments and modified examples.

### REFERENCE SIGNS LIST

1 First ferromagnetic layer
2 Second ferromagnetic layer
3 Non-magnetic layer
10, 10′, 15 Magnetoresistive effect element
11 Stack
12 Spin-orbit torque wiring
20 Substrate
30 First layer
31, 34, 36, 38, 38A, 38B, 41, 44 Magnetic layer
32, 42 First insulating layer
33, 43 Second insulating layer
35, 37, 45 Insulating layer
40 Second layer
50 First via wiring
51, 61 Electrode
52, 62 Wiring
60 Second via wiring
70 Third via wiring
100, 101, 102, 103, 104, 105, 106, 106A, 106B, 107, 108, 109 Magnetoresistive device
I1, I2 Interface
θ1, θ2 Inclination angle

1. A magnetoresistive device comprising:
a substrate;
a first magnetoresistive effect element;
a first layer which is sandwiched between the substrate and the first magnetoresistive effect element; and
a second layer which is located farther from the substrate than the first magnetoresistive effect element in a stacking direction,
wherein the first magnetoresistive effect element includes a stack and a spin-orbit torque wiring in contact with the stack,
wherein the stack includes a first ferromagnetic layer, a second ferromagnetic layer, and a non-magnetic layer sandwiched between the first ferromagnetic layer and the second ferromagnetic layer, and
wherein only one of the first layer or the second layer includes an insulating first magnetic layer or,
wherein the first layer includes an insulating first magnetic layer, the second layer includes an insulating second magnetic layer, and the first magnetic layer and the second magnetic layer are electrically separated from each other.

2. The magnetoresistive device according to claim 1, wherein the first layer includes an insulating first magnetic layer.

3. The magnetoresistive device according to claim 2,
wherein the first layer includes a first insulating layer between the first magnetic layer and the substrate.

4. The magnetoresistive device according to claim 2,
wherein the first layer includes a second insulating layer between the first magnetic layer and the first magnetoresistive effect element.

5. The magnetoresistive device according to claim 1,
wherein the first layer includes an insulating first magnetic layer, and
wherein the second layer includes an insulating second magnetic layer.

6. The magnetoresistive device according to claim 1,
wherein the first magnetic layer contains an oxide containing at least a magnetic element and oxygen.

7. The magnetoresistive device according to claim 1,
wherein the first magnetic layer contains ferrite, and
wherein the ferrite contains one or more atoms selected from the group consisting of Mn, Zn, Ni, Cu, Ba, Sr, Pb, and Co as well as Fe and O.

8. The magnetoresistive device according to claim 1, further comprising:
a first via wiring which is connected to the spin-orbit torque wiring; and
a second via wiring which is connected to the spin-orbit torque wiring at a position different from the first via wiring,
wherein the first via wiring or the second via wiring includes an electrode which is in contact with the spin-orbit torque wiring and a wiring which extends from the electrode in a stacking direction.

9. The magnetoresistive device according to claim 8,
wherein the electrode contains a metal or alloy containing W, Ta, Ru, or Co, or a nitride of Ti, V, Cr, Zr, Nb, Mo, Ta, or W.

10. The magnetoresistive device according to claim 1, further comprising:
a first via wiring which is connected to the spin-orbit torque wiring; and
a second via wiring which is connected to the spin-orbit torque wiring at a position different from the first via wiring,
wherein at least one of the first via wiring and the second via wiring penetrates the first magnetic layer.

11. The magnetoresistive device according to claim 1, further comprising:
a first via wiring which is connected to the spin-orbit torque wiring; and
a second via wiring which is connected to the spin-orbit torque wiring at a position different from the first via wiring,
wherein the first magnetic layer is located between the first via wiring and the second via wiring when viewed from a stacking direction.

12. The magnetoresistive device according to claim 1, further comprising:
a plurality of magnetoresistive effect elements,
wherein each of the plurality of magnetoresistive effect elements is located at the same layer as the first magnetoresistive effect element in a stacking direction,
wherein each of the plurality of magnetoresistive effect elements includes the stack and the spin-orbit torque wiring, and
wherein the first magnetic layer is located between the first magnetoresistive effect element and the magnetoresistive effect element adjacent to the first magnetoresistive effect element when viewed from a stacking direction.

13. The magnetoresistive device according to claim 1, further comprising:
a plurality of magnetoresistive effect elements,
wherein each of the plurality of magnetoresistive effect elements is located at the same layer as the first magnetoresistive effect element in a stacking direction,
wherein each of the plurality of magnetoresistive effect elements includes the stack and the spin-orbit torque wiring,
wherein the first via wiring and the second via wiring are connected to the spin-orbit torque wirings of the first magnetoresistive effect element and the plurality of magnetoresistive effect elements, and wherein the first magnetic layer surrounds the periphery of each of the first via wiring and the second via wiring when viewed from a stacking direction.

14. The magnetoresistive device according to claim 1, further comprising:
a plurality of magnetoresistive effect elements,
wherein each of the plurality of magnetoresistive effect elements is located at the same layer as the first magnetoresistive effect element in a stacking direction,
wherein each of the plurality of magnetoresistive effect elements includes the stack and the spin-orbit torque wiring,
wherein the first via wiring and the second via wiring are connected to the spin-orbit torque wirings of the first magnetoresistive effect element and the plurality of magnetoresistive effect elements,
wherein the first magnetoresistive effect element and the plurality of magnetoresistive effect elements are arranged in a matrix, and
wherein the first magnetic layer is located between the first via wiring and the second via wiring of each magnetoresistive effect element belonging to a first column and between the magnetoresistive effect elements belonging to a second column adjacent to the first column when viewed from a stacking direction.

15. The magnetoresistive device according to claim 1, further comprising:
a plurality of magnetoresistive effect elements,
wherein each of the plurality of magnetoresistive effect elements is located at the same layer as the first magnetoresistive effect element in a stacking direction,
wherein each of the plurality of magnetoresistive effect elements includes the stack and the spin-orbit torque wiring,
wherein the first via wiring and the second via wiring are connected to the spin-orbit torque wirings of the first magnetoresistive effect element and the plurality of magnetoresistive effect elements, and
wherein the first magnetic layer surrounds a pair of the first via wiring and the second via wiring when viewed from a stacking direction.

16. The magnetoresistive device according to claim 3, further comprising:
a first via wiring which is connected to the spin-orbit torque wiring; and
a second via wiring which is connected to the spin-orbit torque wiring at a position different from the first via wiring,
wherein the first via wiring penetrates the first magnetic layer and the first insulating layer, and
wherein an inclination angle of an interface between the first via wiring and the first magnetic layer with respect to a stacking direction is larger than an inclination angle of an interface between the first via wiring and the first insulating layer with respect to a stacking direction.

17. The magnetoresistive device according to claim 1, further comprising:
a third via wiring which is connected to the stack,
wherein the second layer includes an insulating first magnetic layer, and
wherein the first magnetic layer coats the periphery of the third via wiring.

18. A magnetoresistive device comprising:
a substrate;
a first magnetoresistive effect element;
a first layer which is sandwiched between the substrate and the first magnetoresistive effect element; and
a second layer which is disposed at a position farther from the substrate than the first magnetoresistive effect element in a stacking direction,
wherein the first magnetoresistive effect element includes a first ferromagnetic layer, a second ferromagnetic layer, and a non-magnetic layer sandwiched between the first ferromagnetic layer and the second ferromagnetic layer, and
wherein the first layer or the second layer includes an insulating first magnetic layer.

19. A magnetic memory comprising:
the magnetoresistive device according to claim 1.
